(19) United States
(12) Patent Application Publication
(10) Pub. No.: US 2026/0197939 A1
(43) Pub. Date: Jul. 9, 2026

(54) PRINTED CIRCUIT BOARD STRUCTURE FOR OPTICAL TRANSCEIVER AND OPTICAL TRANSCEIVER

(71) Applicant: Aivres Systems Inc., San Jose, CA (US)

(72) Inventor: Tzu Ching Yang, New Taipei City (TW)

(21) Appl. No.: 19/013,496

(22) Filed: Jan. 8, 2025

(51) Int. Cl. H05K 1/11; H05K 1/02

(52) U.S. Cl. CPC H05K 1/112; H05K 1/0274; H05K 1/118; H05K 1/119; H05K 2201/09481

(57) ABSTRACT

A PCB structure includes a flexible PCB and a rigid PCB. The flexible PCB has first soldering pads connected to at least one first conducting line. The at least one first conducting line has a first width. The rigid PCB has second soldering pads connected to at least one second conducting line. The at least one second conducting line has a second width greater than the first width. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads.

### TECHNICAL FIELD

This disclosure is generally related to printed circuit board structures for optical transceivers and optical transceivers having the same.

### BACKGROUND

With the development of science and technology and the rapid growth of the required data transmission traffic, both server data and wireless communication must have higher speed signal transmission to meet the current network demand. The 100G Ethernet specification and architecture have also been proposed in recent years, and the latest 802.3bm standard was approved on Feb. 16, 2015. The 802.3bm standard specifies the physical layer (PHY) of the lower-cost optical 100GBASE-SR4, utilizing multimode fibers and a four-channel, chip-to-module and chip-to-chip electrical specifications (CAUI-4).

### SUMMARY

Described herein are printed circuit board (PCB) structures for optical transceivers and optical transceivers having the same.

In one general aspect, a PCB structure is provided. The PCB structure includes a flexible PCB and a rigid PCB. The flexible PCB has first soldering pads connected to at least one first conducting line. The at least one first conducting line has a first width. The rigid PCB has second soldering pads connected to at least one second conducting line. The at least one second conducting line has a second width greater than the first width. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads.

In some embodiments, the via corresponds to a middle pad of the second soldering pads.

In some embodiments, an area of the via is greater than an area of the middle pad.

In some embodiments, the via does not extend to within second soldering pads immediately adjacent to the middle pad.

In some embodiments, two edges of the via coincide with two edges of the second soldering pads immediately adjacent to the middle pad.

In some embodiments, the middle pad and the via are of a rectangular shape, wherein edges of the middle pad are in parallel with edges of the via.

In some embodiments, from a top view, the middle pad is within the via.

In some embodiments, the rigid PCB further comprises at least one third pad separated from the second soldering pads.

In some embodiments, the at least one third pad is connected to ground.

In another general aspect, an optical transceiver is provided. The optical transceiver includes a flexible PCB, a rigid PCB, and an optical connector connected to the rigid PCB. The flexible PCB has first soldering pads connected to at least one first conducting line. The at least one first conducting line has a first width. The rigid PCB has second soldering pads connected to at least one second conducting line. The at least one second conducting line has a second width greater than the first width. The optical connector is connected to the rigid PCB. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads.

In yet another general aspect, an optical transceiver is provided. The optical transceiver includes a flexible PCB, a rigid PCB, and an optical connector connected to the rigid PCB. The flexible PCB has an electronic header and first soldering pads connected to at least one first conducting line. The at least one first conducting line has a first width. The rigid PCB has second soldering pads connected to at least one second conducting line. The at least one second conducting line has a second width greater than the first width. The optical connector is connected to the rigid PCB. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads. In some embodiments, the electronic header is configured to connect to an adapter.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 shows an optical transceiver module for a high-speed Ethernet network according to one example embodiment.

FIG. 2 is a side view of an optical receiver according to one example embodiment.

FIG. 3 is a top view of the PCB structure as shown in FIG. 2, according to one example embodiment.

FIG. 4A is a top view of a rigid PCB according to one example embodiment.

FIG. 4B shows a cross-sectional view at line AA in FIG. 4A, according to one example embodiment.

FIG. 5 depicts a cross view of the layers for a rigid PCB, according to one example embodiment.

FIGS. 6A and 6B illustrate the reflection coefficient (S11) and insertion loss (S21) for the conventional design.

FIGS. 7A and 7B shows the measured phase and group delay, respectively, for the conventional PCB structure.

FIGS. 8A and 8B illustrate the reflection coefficient (S11) and insertion loss (S21) for the disclosed design.

FIGS. 9A and 9B shows the measured phase and group delay, respectively, for the disclosed PCB structure.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

In general, metal pins of the coaxial optical module are directly cut short and welded to the rigid board. However, as the transmission rate increases, this welding structure lacks an effective mode of electromagnetic conduction, such that the transmission bandwidth is limited by the parasitic inductance generated by the pins. On the 10 Gb/s optical module, the flexible board may be used to connect the optical sub-module with the rigid PCB board. The use of flexible boards to connect optical sub-modules with rigid boards is a powerful candidate for the new generation of 25 Gb/s optical transceivers, because the flexible board is highly flexible, can change shape according to space constraints, and has the advantages of three-dimensional wiring. The connection between optical sub-modules and rigid boards can maintain the effective mode of electromagnetic conduction, and has the advantages of being thin.

When the flexible board is used in the 25 Gb/s optical transceiver module, it should be determined whether the transmission bandwidth of the flexible board can meet the technical needs. For example, the signal quality between the single microstrip line and the ground common plane waveguide is investigated. Further, the relationship between the transmission line length and loss, and the dielectric constant and loss factor of the insulating material of the flexible board are all factors that are considered in the production of the flexible board.

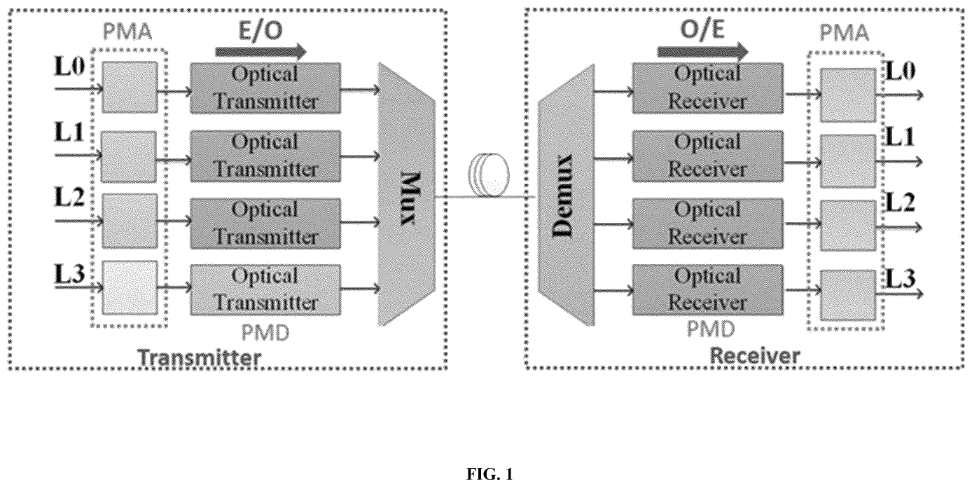

FIG. 1 shows an optical transceiver module, when the encoded data is received by the PMA (Physical Media Adapter) in the physical layer (PHY) of a high-speed Ethernet network. It is serialized into a non-return-to-zero (NRZ) signal, which is then transmitted to the optical transmitter module in the Physical Media Dependent (PMD) to convert the telecommunication signal into an optical signal, and the optical signals of different wavelengths in the four optical transmitter channels are then passed through the multitasker (MUX). The 25.781 Gb/s NRZ signals of four wavelengths is coupled into a single fiber to achieve the goal of 100 Gb/s transmission rate of a single fiber. On the receiver side, the light is separated into four wavelengths by a demultitasker (DEMUX) at the receiving terminal. The optical receiver module in the PMD converts the optical signal into telecommunication signals, which is then processed in the PMA.

The optical transceiver module may include an optical sub-assembly (OSA) and an electrical sub-assembly (ESA). In the early days, optical and electrical modularization was based on wire bonding of optical components and electrical components on the circuit board. With the increase of transmission rate, the packaging of the module and the connection method of the components would affect the overall bandwidth and signal quality. The connection method of wire bonding lacks effective electromagnetic conduction, and the metal of the wire bonding will also produce additional inductive effects to affect the signal quality.

When the transmission rate of optical transceiver modules exceeds 25 Gb/s, many research groups have begun to use flexible printed circuit boards (FPCBs) to connect optical sub-modules and electrical sub-modules. In the study of the 25 Gb/s optical transceiver module, a flexible printed circuit board may be used to connect the optical sub-modules of the laser package with the electrical sub-modules of the rigid circuit board. Among them, the flexible printed circuit board has the advantages of small size, light weight, flexibility and three-dimensional wiring, and can effectively maintain electromagnetic conduction when applied to the connection between optical and electrical modules.

There are several challenges in the design of flexible printed circuit boards. First, the connection between flexible printed circuit boards and rigid printed circuit boards is different due to the different stacking of the two boards, and the line width and line spacing of the signal transmission lines are also different. The need to reduce the signal loss derived from the connection is achieved through design impedance matching. Second, due to different design considerations, the line width and spacing of the signal transmission lines are different from the size of the solder pads on the packaged optical submodule. Thirdly, due to the small size and size of the flexible board, the selection of circuit board materials and the process capability of the board factory would affect the design quality of the module, resulting in the problem of signal transmission limitation or insufficient bandwidth.

The disclosed techniques can reduce the transmission loss caused by the interface surface. The mismatch between the resonance point and impedance generated at the flexible PCB and rigid PCB interface may cause excessive signal reflection, which leads to the deterioration of the output optical waveform. The disclosed techniques provide appropriate optimization design to compensate for these problems.

The disclosed techniques reduce the deterioration caused by the flexible board construction method when the high-speed signal is in use. The optimal design of welding between flexible and rigid boards is proposed. In some embodiments, the design at the connection point may be a ground-signal-ground (GSG) design, where the signal line structure without a GND layer on the guide hole (Via) and the flexible board generates parasitic inductance. The disclosed techniques include optimal design of the solder joint.

Various embodiments described herein are directed to PCB structures for optical transceivers and optical transceivers having such PCB structures. In one embodiment, a PCB structure is provided. The PCB structure includes a flexible PCB and a rigid PCB. The flexible PCB has first soldering pads connected to at least one first conducting line. The at least one first conducting line has a first width. The rigid PCB has second soldering pads connected to at least one second conducting line. The at least one second conducting line has a second width greater than the first width. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads.

In another embodiment, an optical transceiver is provided. The optical transceiver includes a flexible PCB, a rigid PCB, and an optical connector connected to the rigid PCB. The flexible PCB has first soldering pads connected to at least one first conducting line. The at least one first conducting line has a first width. The rigid PCB has second soldering pads connected to at least one second conducting line. The at least one second conducting line has a second width greater than the first width. The optical connector is connected to the rigid PCB. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads.

In another embodiment, an optical transceiver is provided. The optical transceiver includes a flexible PCB, a rigid PCB, and an optical connector connected to the rigid PCB. The flexible PCB has an electronic header and first soldering pads connected to at least one first conducting line. The at least one first conducting line has a first width. The rigid PCB has second soldering pads connected to at least one second conducting line. The at least one second conducting line has a second width greater than the first width. The optical connector is connected to the rigid PCB. The rigid PCB includes a first conductive layer connected to the second soldering pads, a second conductive layer connected to ground, a third conductive layer connected to the ground, a first insulation layer interposed between the first conductive layer and the second conductive layer; and a second insulation layer interposed between the second conductive layer and the third conductive layer. The second conductive layer includes a via immediately under the second soldering pads.

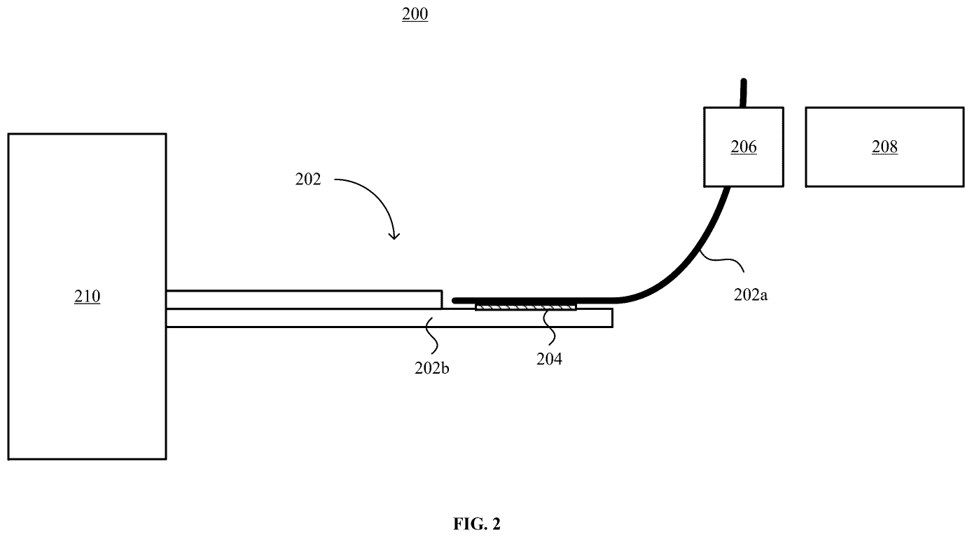

Further embodiments will now be explained with the accompanying figures. Reference is first made to FIG. 2. FIG. 2 is a side view of an optical receiver 200 according to one example embodiment. The optical receiver 200 includes a PCB structure 202. The PCB structure 202 includes a flexible PCB 202a and a rigid PCB 202b. The flexible PCB 202a and the rigid PCB 202b are connected to each other by solder 204. In some embodiments, the flexible PCB 202a further may include an electronic header 206 that is configured to connect to an adapter 208. The optical receiver 200 further includes an optical connector 210 connected to the rigid PCB 202b. The disclosed techniques provide a novel and inventive connection design to reduce the impedance between the flexible PCB 202a and the rigid PCB 202b. In some embodiments, the design reduce the signal reflection at the interface between the flexible PCB 202a and the rigid PCB 202b.

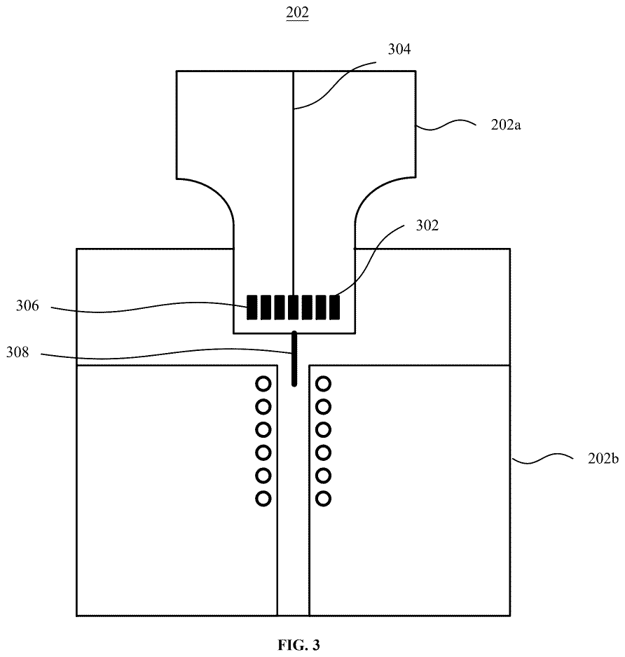

FIG. 3 is a top view of the PCB structure 202 according to one example embodiment. The flexible PCB 202a includes first soldering pads 302 connected to at least one first conducting line 304. The rigid PCB 202b includes second soldering pads 306 connected to at least one second conducting line 308. The at least one first conducting line 304 has a width narrower than a width of the at least one second conducting line 308. In some embodiments, each of the first soldering pads 302 on the flexible PCB 202a may be connected to a wiring/conducting line 304 of the flexible PCB 202a. Each of the second soldering pads 306 on the rigid PCB 202b may be connected to a wiring/conducting line 308. Because the first conducting line 304 has a width narrower than the width of the second conducting line 308, the high-frequency signals may experience impedance at the interface of the flexible PCB 202a and the rigid PCB 202b.

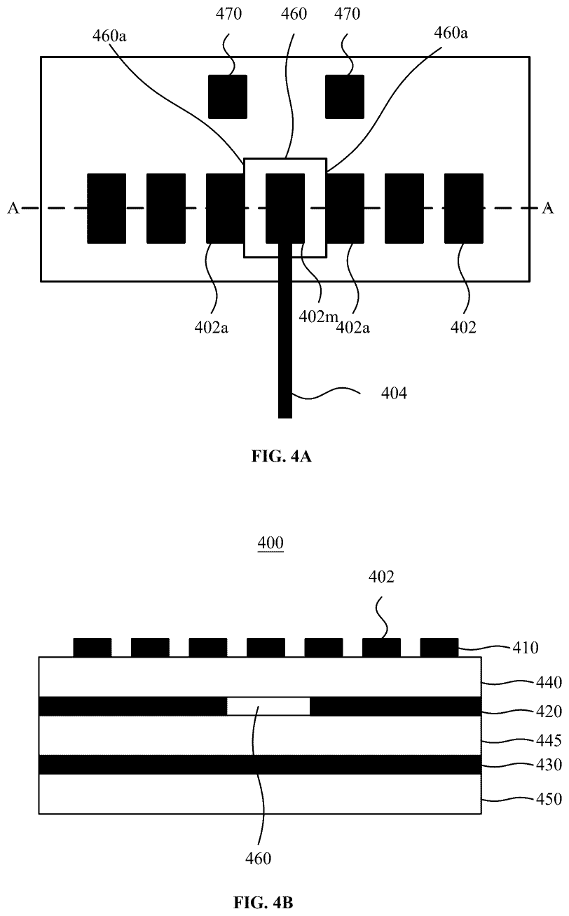

To solve the issue, the disclosed techniques provide a rigid PCB 400 as shown in FIG. 4A. FIG. 4A is a top view of the rigid PCB according to one example embodiment. The rigid PCB 400 includes a plurality of soldering pads 402 connected to at least one wiring/conducting line 404. In some embodiments, each of the soldering pads 402 is connected to a wiring/conducting line 404. The rigid PCB 400 has a multilayered structure. FIG. 4B shows a cross-sectional view at line AA in FIG. 4A, according to one example embodiment. The rigid PCB 400 includes a first conductive layer 410 connected to the soldering pads 402, a second conductive layer 420 connected to the ground, a third conductive layer 430 connected to the ground, a first insulation layer 440 interposed between the first conductive layer 410 and the second conductive layer 420, and a second insulation layer 445 interposed between the second conductive layer 420 and the third conductive layer 430. The second conductive layer 420 includes a via 460 immediately under the soldering pads 402. In some embodiments, the via 460 may be filled with an insulation material, such as the first insulation layer 440 or the second insulation layer 445. Since the second conductive layer 420 includes the via 460 immediately under the soldering pad 402 that is connected to the wiring 404, the soldering pad 402 now has a reference ground at the third conductive layer 430, instead of the second conductive layer 420.

The structure result in an increase in impedance at the soldering pad 402 that is connected to the wiring 404. This creates a more balanced impendence difference between the soldering pad (e.g., pad 302 of FIG. 3) of the flexible PCB that is connected to a narrower wiring (e.g., wiring 304 of FIG. 3) and the soldering pad 402 that is connected to a wider wiring 404. The final PCB structure reduces signal loss due to reflection at the interface created by impedance imbalance, and effective to transmit high speed/frequency signals between the flexible PCB and the rigid PCB.

In some embodiments, referring again to FIG. 4B, the rigid PCB 400 may further include a third insulation layer 450 disposed under the third conductive layer 430 to insulate and protect the third conductive layer 430. In some embodiments, the rigid PCB 400 may further include anti-soldering coating (not shown) on the first conductive layer 410 to protect the first conductive layer 410. The anti-soldering coating includes openings to expose the soldering pads 402.

In some embodiments, the first conductive layer 410, the second conductive layer 420, and the third conductive layer 430 may be made of suitable metal or alloy, such as copper, gold, silver, etc. In some embodiments, the first insulation layer 440, the second insulation layer 445, and the third insulation layer 450 are mode of one or more suitable insulating materials, such as polypropylene or composite laminates (e.g., Roger 4350B, FR4, etc.) that provides tunable dielectric property for the PCB.

In some embodiments, the rigid PCB 400 may include more than three conductive layers and three insulation layers depending on the actual needs of the optical transceiver.

In some embodiments, the via can be immediately under the pad or pads are that connected to a wire or wires, and can have a size greater than the pad or pads.

Referring to FIGS. 4A and 4B, in some embodiments, the via 460 corresponds to a middle pad 402m of the soldering pads 402. In some embodiments, an area of the via 460 is greater than an area of the middle pad 402m. In some embodiments, the via 460 does not extend to within second soldering pads 402a immediately adjacent to the middle pad 402m. In some embodiments, two edges 460a of the via 460 coincide with two edges of the second soldering pads 402a immediately adjacent to the middle pad 402m. In some embodiments, the middle pad 402m and the via 460 are of a rectangular shape, wherein edges of the middle pad 402m are in parallel with edges of the via 406 from the top view. In some embodiments, from a top view, the middle pad 402m is within the via 460.

In some embodiments, the rigid PCB 400 further includes at least one third pad 470 separated from the second soldering pads 402. In some embodiments, the at least one third pad 470 is connected to ground. The inclusion of the third pad(s) 470 can effectively reduce the signal reflection at some particular frequency/frequencies to improve the overall high frequency signal transmission between the flexible PCB and the rigid PCB.

### EXAMPLES

DuPont AP9131R is used for the flexible copper foil substrate, and DuPont FR7013 is used for the covering film with the TGMSL structure, 4.8 mil line width and 10 mil pitch (Gap). The HFSS software is used to design the flexible PCB, while the flexible PCB has a long length of 16.5 mm and a width of 15 mm. The flexible PCB is welded with the rigid PCB at a short length of 7.32 mm. The design of the solder joints of the flexible PCB includes a pad length of 1.2 mm and a width of 0.58 mm. The spacing between the pads is 0.2 mm.

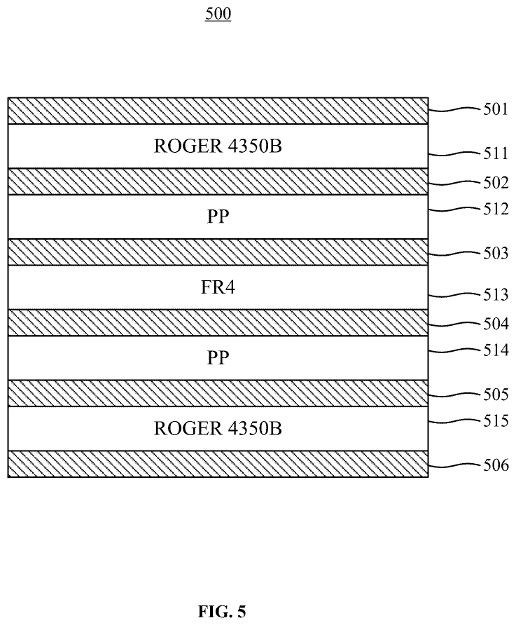

Six conductive layers is used for the rigid PCB. FIG. 5 depicts a cross view of the layers for the rigid PCB 500, according to one example embodiment. The rigid PCB 500 includes conductive layers 501-506 and five insulation layers 511-515. The high-frequency insulation layers 511 and 515 use Roger4350B, which has a dielectric constant of 3.33. Insulation layers 512 and 514 use PP, which the middle insulation layer 513 uses FR4. The conductive layers 501-506 use copper as the material.

One conventional PCB structure where the rigid PCB has no via immediately under the soldering pads and one disclosed PCB structure where the rigid PCB has a via immediately under the soldering pads are prepared. Both structures are tested for performance.

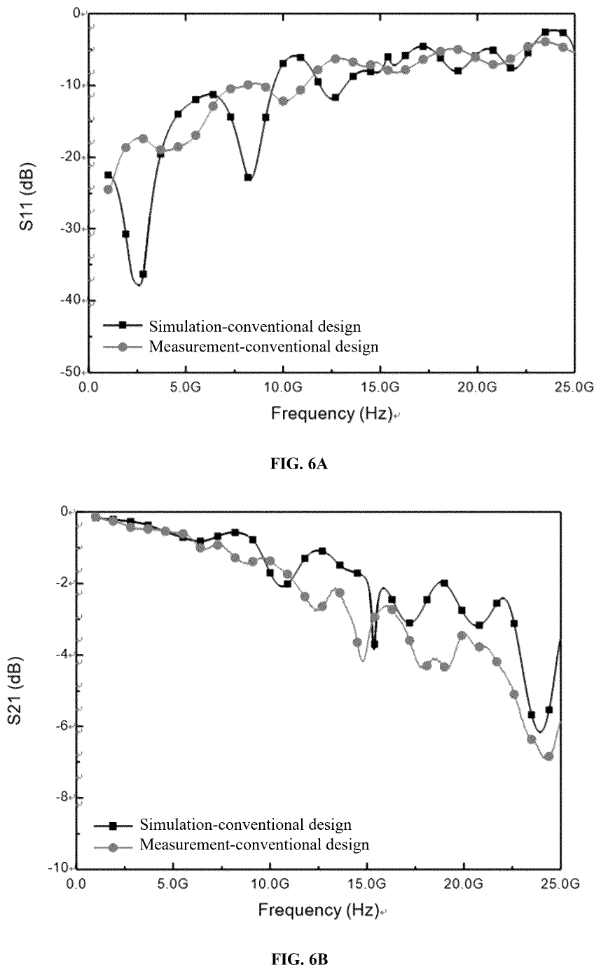

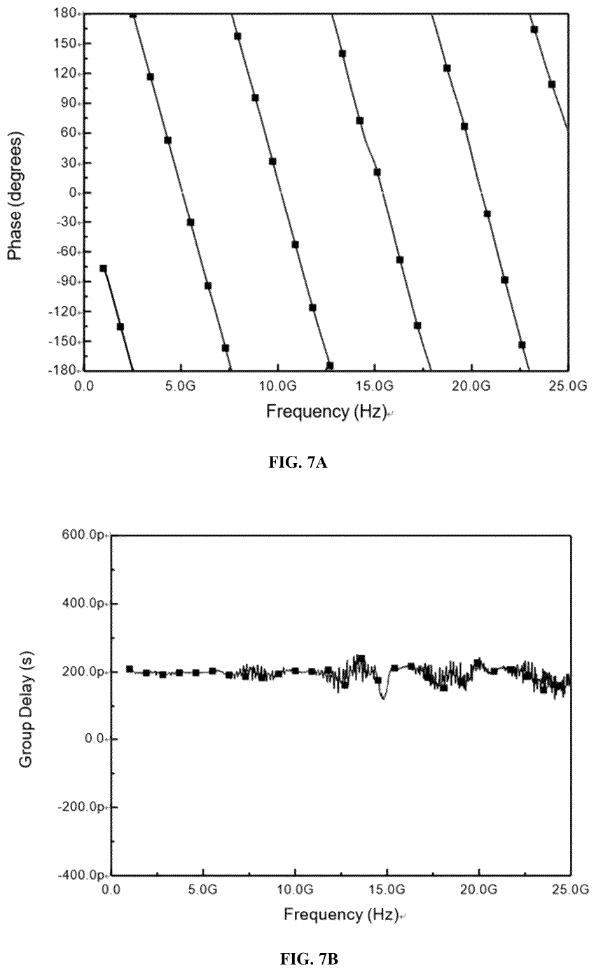

Both simulation and a vector network analyzer (Agilent 8722ES) are used for measuring the reflection coefficient (S11) and insertion loss (S21) for the conventional design and the disclosed novel design. FIGS. 6A and 6B illustrate the reflection coefficient (S11) and insertion loss (S21) for the conventional design. The simulated and measured insertion loss diagram as shown in FIG. 6B show a significant resonance point at about 15 GHz, and a bandwidth of 14.2 GHz, which is not sufficient for 25 Gb/s. The reflection coefficient (FIG. 6A) shows that after 11 GHz, the reflection is greater than-10 dB. FIGS. 7A and 7B shows the measured phase and group delay, respectively, for the conventional PCB structure, where the jitter variation in the overall group delay varies from 118 ps to 220 ps, but at 15 GHz there is a large drop in the group delay.

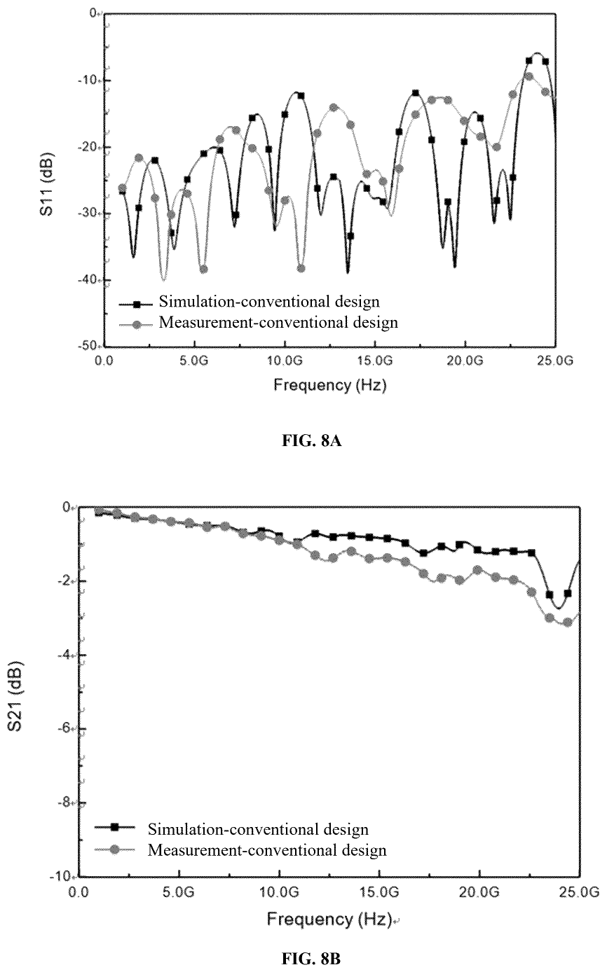

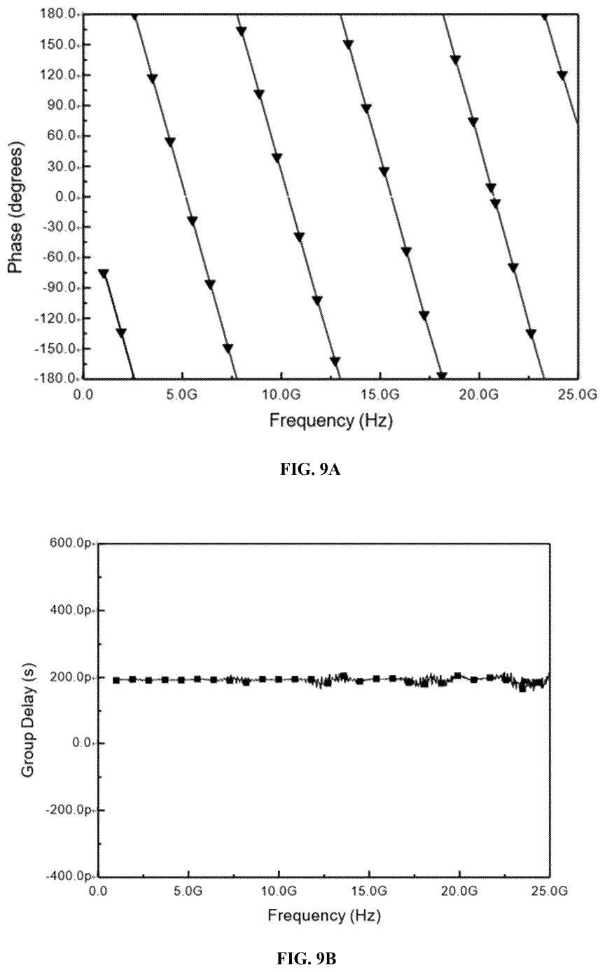

FIGS. 8A and 8B illustrate the reflection coefficient (S11) and insertion loss (S21) for the disclosed novel design. From the insertion loss, FIG. 8B shows that the resonance point has been eliminated at 15 GHz for the disclosed design. The overall bandwidth has also been significantly increased to 23.5 GHZ. According to the reflection coefficient (FIG. 8A), the reflection is suppressed below-10 dB before 23 GHz. FIGS. 9A and 9B shows the measured phase and group delay, respectively, for the disclosed PCB structure. The group delay measurement shows that the resonance point at 15 GHz has been compensated for the disclosed design, while the overall group delay jitter varies from 170 ps to 210 ps. The results indicate that the resonance point is eliminated, the overall bandwidth is increased, and the reflectance is reduced for the disclosed design. The above results for the conventional design and the disclosed design are summarized in Table 1 below.

TABLE 1

| | Not | GND Pad + |
|---|---|---|
| | optimized | Anti Pad |
| Rise time(ps) | 18 | 13.56 |
| Fall time(ps) | 16.22 | 13.11 |
| Jitter(ps) | 6.87 | 6.63 |
| Eye-Height (mV) | 218.22 | 287.27 |
| Eye-Width (ps) | 33.03 | 33.6 |
| Q-factor | 6.58 | 9.98 |

Based on these results, it can be found that in the conventional design there is a resonance point at about 15 GHz and the overall bandwidth is insufficient, and that the S11 curve shows that the reflection is greater than-10 dB at 7 GHz. The disclosed novel design successfully eliminates the resonance points generated at about 15 GHz. Due to the difference in line widths of the lines on the flexible PCB and the rigid PCB, a serious impedance mismatch at the interface. The improved design removes the grounding layer at the interface of the rigid PCB, and the impedance of the insulating substrate is increased due to the removal of one ground layer. The overall bandwidth is increased, and the reflection is depressed to below-10 dB until 23 GHz. The measured characteristic impedance has been increased from 40-ohms to 49-ohms at the soldering pad of the rigid PCB. The disclosed techniques demonstrates the −3 dB bandwidth reaches 23.5 GHz.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A printed circuit board (PCB) structure comprising:
a flexible PCB having first soldering pads connected to at least one first conducting line, wherein the at least one first conducting line has a first width; and
a rigid PCB having second soldering pads connected to at least one second conducting line, wherein the at least one second conducting line has a second width greater than the first width,
wherein the rigid PCB comprises:
a first conductive layer connected to the second soldering pads;
a second conductive layer connected to ground;
a third conductive layer connected to the ground;
a first insulation layer interposed between the first conductive layer and the second conductive layer; and
a second insulation layer interposed between the second conductive layer and the third conductive layer,
wherein the second conductive layer includes a via immediately under the second soldering pads.

2. The PCB structure of claim 1, wherein the via corresponds to a middle pad of the second soldering pads.

3. The PCB structure of claim 2, wherein an area of the via is greater than an area of the middle pad.

4. The PCB structure of claim 3, wherein the via does not extend to within second soldering pads immediately adjacent to the middle pad.

5. The PCB structure of claim 4, wherein two edges of the via coincide with two edges of the second soldering pads immediately adjacent to the middle pad.

6. The PCB structure of claim 2, wherein the middle pad and the via are of a rectangular shape, wherein edges of the middle pad are in parallel with edges of the via.

7. The PCB structure of claim 6, wherein from a top view, the middle pad is within the via.

8. The PCB structure of claim 1, wherein the rigid PCB further comprises at least one third pad separated from the second soldering pads.

9. The PCB structure of claim 8, wherein the at least one third pad is connected to ground.

10. An optical transceiver comprising:
a flexible printed circuit board (PCB) having first soldering pads connected to at least one first conducting line, wherein the at least one first conducting line has a first width;
a rigid PCB having second soldering pads connected to at least one second conducting line, wherein the at least one second conducting line has a second width greater than the first width; and
an optical connector connected to the rigid PCB,
wherein the rigid PCB comprises:
a first conductive layer connected to the second soldering pads;
a second conductive layer connected to ground;
a third conductive layer connected to the ground;
a first insulation layer interposed between the first conductive layer and the second conductive layer; and
a second insulation layer interposed between the second conductive layer and the third conductive layer,
wherein the second conductive layer includes a via immediately under the second soldering pads.

11. The optical transceiver of claim 10, wherein the via corresponds to a middle pad of the second soldering pads.

12. The optical transceiver of claim 11, wherein an area of the via is greater than an area of the middle pad.

13. The optical transceiver of claim 12, wherein the via does not extend to within second soldering pads immediately adjacent to the middle pad.

14. The optical transceiver of claim 13, wherein two edges of the via coincide with two edges of the second soldering pads immediately adjacent to the middle pad.

15. The optical transceiver of claim 11, wherein the middle pad and the via are of a rectangular shape, wherein edges of the middle pad are in parallel with edges of the via.

16. The optical transceiver of claim 15, wherein from a top view, the middle pad is within the via.

17. The optical transceiver of claim 10, wherein the rigid PCB further comprises at least one third pad separated from the second soldering pads.

18. The optical transceiver of claim 17, wherein the at least one third pad is connected to ground.

19. An optical transceiver comprising:
a flexible printed circuit board (PCB) comprising an electronic header and first soldering pads connected to the electronic header through at least one first conducting line, wherein the at least one first conducting line has a first width;
a rigid PCB having second soldering pads connected to at least one second conducting line, wherein the at least one second conducting line has a second width greater than the first width; and
an optical connector connected to the rigid PCB,
wherein the rigid PCB comprises:
a first conductive layer connected to the second soldering pads;
a second conductive layer connected to ground;
a third conductive layer connected to the ground;
a first insulation layer interposed between the first conductive layer and the second conductive layer; and
a second insulation layer interposed between the second conductive layer and the third conductive layer,
wherein the second conductive layer includes a via immediately under the second soldering pads.

20. The optical transceiver of claim 19, wherein the electronic header is configured to connect to an adapter.
